(19) United States
(12) Patent Application Publication
(10) Pub. No.: US 2024/0052203 A1
(43) Pub. Date: Feb. 15, 2024

(54) POLISHING COMPOSITION AND POLISHING METHOD USING THE SAME

(71) Applicant: FUJIMI INCORPORATED, Aichi (JP)

(72) Inventor: RYO WAKABAYASHI, Aichi (JP)

(73) Assignee: FUJIMI INCORPORATED, Aichi (JP)

(21) Appl. No.: 18/266,750

(22) PCT Filed: Nov. 10, 2021
(86) PCT No.: PCT/JP2021/041319

§ 371 Date: Jun. 12, 2023

(30) Foreign Application Priority Data
Dec. 17, 2020 (JP) 2020-209498

(51) Int. Cl. C09G 1/02

(52) U.S. Cl. CPC C09G 1/02

(57) ABSTRACT

The present invention is to provide a means for reducing surface roughness (Ra) while maintaining a high polishing rate in polishing of an object to be polished containing a resin and a filler. A polishing composition of the present invention comprises alumina particles, colloidal silica particles, and a dispersing medium for use in polishing an object to be polished containing a resin and a filler, in which the alumina particles have an average particle size of less than 2.8 μm, and the colloidal silica particles have an average particle size less than the average particle size of the alumina particles.

### TECHNICAL FIELD

The present invention relates to a polishing composition and a polishing method using the same.

### BACKGROUND ART

In recent years, along with advancement in high integration and improved performance of LSI, new micromachining techniques have been developed. A chemical mechanical polishing (hereinafter, also abbreviated to “CMP”) method is one of the techniques, and frequently used in a step of manufacturing an LSI, particularly in a step of forming a multilayer wiring.

The CMP method is used also in polishing a resin surface. The application of the CMP method allows to obtain a resin product having few defects on a surface. Accordingly, various study of a polishing composition for polishing various materials including resins have been made.

Japanese Patent Laid-Open No. 2016-183212 discloses a polishing composition for use in polishing an object to be polished containing a resin with high rigidity and high strength. More specifically, Japanese Patent Laid-Open No. 2016-183212 discloses that even a resin with high rigidity and high strength can be polished at a high polishing rate by using a polishing composition containing abrasive grains having a Mohs hardness and a surface acid level equal to or more than specified values, respectively, and a dispersing medium. Further, Japanese Patent Laid-Open No. 2016-183212 also discloses that abrasive grains mainly composed of α-alumina are preferred from the viewpoint of a polishing rate.

Japanese Patent Laid-Open No. 2007-063442 discloses a polishing composition for use in polishing an object to be polished made of a synthesized resin. More specifically, Japanese Patent Laid-Open No. 2007-063442 discloses that use of a polishing composition containing a polyurethane-based polymer surfactant with a specific structure and having a specific viscosity range, can prevent reduction in amount and polishing ability of the polishing composition in polishing a synthesized resin. Further, Japanese Patent Laid-Open No. 2007-063442 also discloses that a polishing composition further containing α-alumina as abrasive grains is preferred from the viewpoint of a polishing rate.

### SUMMARY OF INVENTION

However, there is a contradiction problem in the techniques described in Japanese Patent Laid-Open No. 2016-183212 and Japanese Patent Laid-Open No. 2007-063442, i.e., surface roughness (Ra) of a resin increases, though a high polishing rate can be achieved.

Accordingly, an object of the present invention is to provide a means for reducing surface roughness (Ra) while maintaining a high polishing rate in polishing an object to be polished containing a resin.

The present inventor has performed extensive study to solve the problem. As a result, the present inventor has found that the problem can be solved by using as abrasive grains alumina particles having a specific particle size and colloidal silica particles smaller than the alumina particles in combination, so that the present invention has been completed.

Specifically, the problem of the present invention can be solved by the following means:

A polishing composition comprising alumina particles, colloidal silica particles, and a dispersing medium for use in polishing an object to be polished containing a resin and a filler, wherein the alumina particles have an average particle size of less than 2.8 μm, and the colloidal silica particles have an average particle size less than the average particle size of the alumina particles.

### DESCRIPTION OF EMBODIMENTS

Hereinafter, the embodiments of the present invention will be described. The present invention is not limited only to the following embodiments. Various modifications can be made within the scope of the appended claims. Throughout the specification, unless particularly stated otherwise, any expression in a singular form should be understood to encompass the concept of its plural form. Therefore, unless particularly stated otherwise, the article specifying a single form (for example, “a”, “an”, “the”, and the like in the case of English language) should be understood to encompass the concept of its plural form. Further, unless particularly stated otherwise, any term used in the present specification should be understood as a term that is used to have the meaning conventionally used in the relevant technical field. Therefore, unless defined otherwise, all the technical terms and scientific terms used in the present specification have the same meaning as generally understood by a person ordinarily skilled in the art to which the present invention is pertained. If there is any conflict in meaning, the present specification (including the definitions) takes priority.

In the present specification, “X to Y” representing a range means “X or more and Y or less” including X and Y. Unless otherwise specified, operations and measurement of physical properties are performed under conditions at room temperature (in the range of 20° C. or more and 25° C. or less)/a relative humidity of 40% RH or more and 50% RH or less.

### <Polishing Composition>

An embodiment of the present invention relates to a polishing composition including alumina particles, colloidal silica particles, and a dispersing medium for use in polishing an object to be polished comprising a resin and a filler, wherein the alumina particles have an average particle size of less than 2.8 μm, and the colloidal silica particles have an average particle size less than the average particle size of the alumina particles. By using as abrasive grains such specific alumina particles and colloidal silica particles in combination, surface roughness (Ra) can be decreased while keeping a high polishing rate in polishing an object to be polished comprising a resin and a filler. Each of the components contained in the polishing composition according to the present invention will be described in detail below. Hereinafter, the alumina particles may also be referred to as “first abrasive grains” and the colloidal silica particles to as “second abrasive grains”.

### [Abrasive Grain]

### <Alumina Particle (First Abrasive Grain)>

The polishing composition according to the present invention contains alumina particles having an average particle size of less than 2.8 μm as abrasive grains (first abrasive grains). The abrasive grains mechanically polish an object to be polished to improve a polishing rate. Since the alumina particles have sufficient hardness, an effect for improving a polishing rate, in particular, an effect for improving a rate for polishing various materials including a resin, is significant.

The alumina particles have an average particle size (average secondary particle size) of less than 2.8 μm. With alumina particles having an average particle size of 2.8 μm or more, a surface of an object to be polished is excessively roughened after being polished (Comparative Examples 9 and 10 as described below). The average particle size of alumina particles is preferably 2.0 μm or less, more preferably less than 1.5 μm, still more preferably less than 1.2 μm, and particularly preferably less than 0.8 μm. The average particle size of alumina particles is preferably 0.1 μm or more, more preferably 0.2 μm or more, still more preferably more than 0.2 μm, and particularly preferably 0.3 μm or more. Within the above ranges, better balance between improved polishing rate and reduced surface roughness can be achieved. The average particle size of alumina particles is, for example, preferably 0.1 μm or more and 2.0 μm or less, more preferably 0.2 μm or more and less than 1.5 μm, still more preferably more than 0.2 μm and less than 1.2 μm, and particularly preferably 0.3 μm or more and less than 0.8 μm. The average particle size (average secondary particle size) of alumina particles is a particle size (D₅₀) indicating a 50% cumulative frequency from the small-particle-size side in a volume-based particle size distribution. Here, D₅₀ of alumina particles can be determined by a dynamic light scattering method, a laser diffraction method, a laser scattering method, a pore electrical resistance method or the like. Specifically, the value determined by the measurement method described in the following Examples is employed.

The alumina particles are not particularly limited, and examples thereof may include alumina particles containing at least one selected among α-alumina, γ-alumina, δ-alumina, θ-alumina, η-alumina and κ-alumina.

A concentration (content) of alumina particles is not particularly limited, being preferably 0.01 mass % or more, more preferably 0.1 mass % or more, still more preferably 0.5 mass % or more, particularly preferably 1 mass % or more, and particularly preferably 1.5 mass % or more, relative to the total mass of the polishing composition. As the concentration of alumina particles increases, a polishing rate is more improved. Also, the concentration (content) of alumina particles is preferably 25 mass % or less, more preferably 15 mass % or less, still more preferably 10 mass % or less, furthermore preferably less than 9 mass %, and particularly preferably 8 mass % or less, relative to the total mass of the polishing composition. Within the above ranges, surface roughness can be further reduced, and occurrence of defects such as scratches can be further reduced. The concentration (content) of alumina particles is, for example, preferably 0.01 mass % or more and 25 mass % or less, more preferably 0.1 mass % or more and 15 mass % or less, still more preferably 0.5 mass % or more and 10 mass % or less, particularly preferably 1 mass % or more and less than 9 mass %, and most preferably 1.5 mass % or more and 8 mass % or less, relative to the total mass of the polishing composition. Within the above ranges, better balance between improved polishing rate and reduced surface roughness can be achieved.

The alumina particles may be easily produced with appropriate reference to a known production method (for example, Japanese Patent Laid-Open No. 2017-190267). Alternatively, commercially available alumina particles may be used.

One type of alumina particles may be used alone, or two or more types thereof may be used in combination.

### <Colloidal Silica Particle (Second Abrasive Grain)>

The polishing composition according to the present invention contains as abrasive grains (second abrasive grains) colloidal silica particles having an average particle size less than that of the alumina particles. Since the colloidal silica particles have a lower hardness in comparison with alumina particles, surface roughness can be reduced. The combination of alumina particles for improving a polishing rate and colloidal silica particles for reducing surface roughness allows compatibility between improvement of a polishing rate and reduction of surface roughness, which are in a trade-off relation, to be achieved with good balance.

The colloidal silica particles have an average particle size (average secondary particle size) less than the average particle size (average secondary particle size) of the alumina particles. With colloidal silica particles having an average particle size more than the average particle size of alumina particles, it is difficult to obtain the effect for reducing surface roughness. The average particle size of colloidal silica particles is preferably 0.20 μm or less, more preferably less than 0.20 μm, still more preferably 0.15 μm or less, and particularly preferably less than 0.10 μm. The average particle size of colloidal silica particles is preferably 0.005 μm or more, more preferably 0.02 μm or more, still more preferably 0.06 μm or more, and particularly preferably 0.07 μm or more. Within the above ranges, better balance between improved polishing rate and reduced surface roughness can be achieved. The average particle size of colloidal silica particles is, for example, preferably 0.005 μm or more and 0.20 μm or less, more preferably 0.02 μm or more and less than 0.20 μm, still more preferably 0.06 μm or more and 0.15 μm or less, and particularly preferably 0.07 μm or more and less than 0.10 μm. The average particle size (average secondary particle size) of colloidal silica particles is a particle size (D₅₀) indicating a 50% cumulative frequency from the small-particle-size side in a volume-based particle size distribution. Here, the average particle size (D₅₀) of colloidal silica particles is determined by a dynamic light scattering method, a laser diffraction method, a laser scattering method, a pore electrical resistance method or the like. Specifically, the value determined by the measurement method described in the following Examples is employed.

The colloidal silica particles preferably have a span value [(D₉₀−D₁₀)/D₅₀] of 0.50 or more and 1.00 or less, more preferably have a span value [(D₉₀−D₁₀)/D₅₀] of more than 0.60 and 1.00 or less, still more preferably have a span value [(D₉₀−D₁₀)/D₅₀] of more than 0.80 and 1.00 or less, and particularly preferably have a span value [(D₉₀−D₁₀)/D₅₀] of 0.85 or more and 0.95 or less. Here, the span value [(D₉₀−D₁₀)/D₅₀] is an index representing uniformity of a particle size distribution as determined as follows. The span value [(D₉₀−D₁₀)/D₅₀] is determined by subtracting a particle size (D₁₀), which indicates a 10% cumulative frequency from the small-particle-size side in a volume-based particle size distribution, from a particle size (D₉₀), which indicates a 90% cumulative frequency from the small-particle-size side in a volume-based particle size distribution, and dividing the subtracted value (D₉₀−D₁₀) by a particle size (D₅₀), which indicates a 50% cumulative frequency from the small-particle-size side in a volume-based particle size distribution, to give a value down to the third decimal place which is then rounded to the second decimal place [(D₉₀−D₁₀)/(D₅₀)]. The volume-based particle size distribution is determined by the measurement method described in the following Examples. The less the span value [(D₉₀−D₁₀)/D₅₀] is, the sharper the particle size distribution is. The more the span value [(D₉₀−D₁₀)/D₅₀] is, the broader the particle size distribution is.

Also, a ratio of the average particle size (average secondary particle size) of alumina particles to the average particle size (average secondary particle size) of colloidal silica particles (average particle size of alumina particles/average particle size of colloidal silica particles) is more than 1. The ratio of the average particle size (average secondary particle size) of alumina particles to the average particle size (average secondary particle size) of colloidal silica particles (average particle size of alumina particles/average particle size of colloidal silica particles) is preferably 1.1 or more, more preferably more than 1.5, still more preferably 2.0 or more, and particularly preferably more than 3.0. The ratio of the average particle size (average secondary particle size) of alumina particles to the average particle size (average secondary particle size) of colloidal silica particles (average particle size of alumina particles/average particle size of colloidal silica particles) is preferably 25.0 or less, more preferably less than 20.0, still more preferably less than 15.0, and particularly preferably less than 5.0. Within the above ranges, better balance between improved polishing rate and reduced surface roughness can be achieved. The ratio of the average particle size (average secondary particle size) of alumina particles to the average particle size (average secondary particle size) of colloidal silica particles (average particle size of alumina particles/average particle size of colloidal silica particles) is, for example, preferably 1.1 or more and 25.0 or less, more preferably more than 1.5 and less than 20.0, still more preferably 2.0 or more and less than 15.0, and particularly preferably more than 3.0 and less than 5.0.

A concentration (content) of the colloidal silica particles is not particularly limited, being preferably 0.5 mass % or more, more preferably 1 mass % or more, still more preferably more than 1 mass %, particularly preferably 2 mass % or more, and particularly preferably 2.5 mass % or more, relative to the total mass of the polishing composition. The more the concentration of the colloidal silica particles is, the more improved the polishing rate is. Also, the concentration (content) of the colloidal silica particles is preferably 20 mass % or less, more preferably 15 mass % or less, still more preferably 10 mass % or less, furthermore preferably less than 10 mass %, and particularly preferably 8 mass % or less, relative to the total mass of the polishing composition. Within the above ranges, surface roughness can be further reduced, and occurrence of defects such as scratches can be further reduced. The concentration (content) of colloidal silica particles is, for example, preferably 0.5 mass % or more and 20 mass % or less, more preferably 1 mass % or more and 15 mass % or less, still more preferably more than 1 mass % and 10 mass % or less, particularly preferably 2 mass % or more and less than 10 mass %, and particularly preferably 2.5 mass % or more and 8 mass % or less, relative to the total mass of the polishing composition. Within the above ranges, compatibility between improvement of polishing rate and reduction of surface roughness can be achieved with better balance.

A mixing mass ratio of alumina particles to colloidal silica particles (concentration (content) of alumina particles/concentration (content) of colloidal silica particles) is not particularly limited, being preferably 0.1 or more, more preferably 0.2 or more, still more preferably more than 0.2, and particularly preferably 0.3 or more. The mixing mass ratio of alumina particles to colloidal silica particles (concentration (content) of alumina particles/concentration (content) of colloidal silica particles) is preferably 10.0 or less, more preferably less than 8.0, still more preferably 5.0 or less, and particularly preferably less than 5.0. Within the above ranges, better balance between improved polishing rate and reduced surface roughness can be achieved. The mixing mass ratio of alumina particles to colloidal silica particles (concentration (content) of alumina particles/concentration (content) of colloidal silica particles) is, for example, preferably 0.1 or more and 10.0 or less, more preferably 0.2 or more and less than 8.0, still more preferably more than 0.2 and 5.0 or less, and particularly preferably 0.3 or more and less than 5.0.

The colloidal silica particles may be easily produced with appropriate reference to a known production method. Alternatively, a commercially available colloidal silica particles may be used. Examples of the production method of colloidal silica may include a sodium silicate method, an alkoxide method, and a sol-gel method, and colloidal silica produced by any one thereof may be suitably used as the colloidal silica in the present invention.

In an embodiment, colloidal silica as a raw material is colloidal silica obtained by a sodium silicate method. The sodium silicate method is typically a method in which activated silicic acid obtained through ion exchange from an alkali silicate aqueous solution such as water glass is used as a raw material and subjected to grain growth.

In an embodiment, colloidal silica as a raw material is colloidal silica obtained by an alkoxide method. The alkoxide method is typically a method in which alkoxysilane is used as a raw material and subjected to hydrolytic condensation reaction.

A type of colloidal silica particles for use is not particularly limited, and for example, surface-modified colloidal silica may be used. For example, the colloidal silica particles may have a cationic group. Preferred examples of colloidal silica having a cationic group may include colloidal silica having an amino group(s) immobilized to a surface thereof. Examples of a method for producing the colloidal silica having a cationic group may include a method which comprises immobilizing a silane coupling agent having an amino group such as aminoethyl trimethoxy silane, aminopropyl trimethoxy silane, aminoethyl triethoxy silane, aminopropyl triethoxy silane, aminopropyl dimethyl ethoxy silane, aminopropyl methyl diethoxy silane, or aminobutyl triethoxy silane to a surface of abrasive grain(s) as disclosed in Japanese Patent Laid-Open No. 2005-162533. Thereby, the colloidal silica with amino group(s) immobilized to its surface (amino group-modified colloidal silica) can be obtained.

The colloidal silica particles may have an anionic group. Preferred examples of colloidal silica having an anionic group may include colloidal silica having an anionic group(s) such as a carboxylic acid group, a sulfonic acid group, a phosphonic acid group, or an aluminic acid group immobilized to a surface thereof. A method for producing the colloidal silica having an anionic group is not particularly limited, and examples thereof may include a method which comprises reacting a silane coupling agent having an anionic group at the end thereof with colloidal silica.

As a specific example, a sulfonic acid group(s) may be immobilized to colloidal silica, for example, by a method described in “Sulfonic acid-functionalized silica through of thiol groups”, Chem. Commun. 246-247 (2003). Specifically, colloidal silica having a sulfonic acid group(s) immobilized to the surface thereof can be produced by coupling a silane coupling agent having a thiol group such as 3-mercaptopropyl trimethoxy silane with colloidal silica, and then oxidizing a thiol group(s) with hydrogen peroxide.

Alternatively, in order to immobilize a carboxylic acid group(s) to colloidal silica, for example, a method disclosed in “Novel Silane Coupling Agents Containing a Photolabile 2-Nitrobenzyl Ester for Introduction of a Carboxy Group on the Surface of Silica Gel”, Chemistry Letters, 3, 228-229 (2000) may be employed. Specifically, colloidal silica having a carboxylic acid group(s) immobilized to the surface thereof can be produced by coupling a silane coupling agent containing a photoreactive 2-nitrobenzyl ester with colloidal silica, and then performing photoirradiation.

One type of colloidal silica particles may be used alone, or two or more types thereof may be used in combination.

### [Dispersing Medium]

The polishing composition according to the present invention contains a dispersing medium. The dispersing medium disperses or dissolves each of the components.

The dispersing medium preferably contains water. Further, from the viewpoint of preventing impurities from affecting other components of the polishing composition, it is preferable to use water as pure as possible. Specifically, pure water or ultra-pure water prepared by removing impurity ions through an ion exchange resin and then removing foreign substances through a filter, or distilled water is preferred. Also, as the dispersing medium, an organic solvent or the like may be further included to control dispersibility and the like of other component(s) of the polishing composition.

### [pH Adjusting Agent]

It is preferable that the polishing composition according to an embodiment of the present invention further contains a pH adjusting agent. Through selection of type and added amount thereof, the pH adjusting agent can contribute to adjustment of pH of the polishing composition.

The pH adjusting agent is not particularly limited as long as it is a compound having a pH adjusting function, and a known compound may be used. The pH adjusting agent is not particularly limited as long as it is the one having a pH adjusting function, and examples thereof include acids and alkalis.

As the acid, any of an inorganic acid and an organic acid may be used. The inorganic acid is not particularly limited, and examples thereof may include sulfuric acid, nitric acid, boric acid, carbonic acid, hypophosphorous acid, phosphorous acid, and phosphoric acid. The organic acid is not particularly limited, and examples thereof may include carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid and lactic acid, and methane sulfonic acid, ethane sulfonic acid and isethionic acid. Among these, organic acids are preferred, and malic acid, citric acid and maleic acid are more preferred. In the case of using an inorganic acid, nitric acid, sulfonic acid or phosphoric acid is preferred.

The alkali is not particularly limited, and examples thereof may include hydroxides of alkali metal such as potassium hydroxide, ammonia, quaternary ammonium salts such as tetramethylammonium and tetraethylammonium, and amines such as ethylenediamine and piperazine. Among these, potassium hydroxide and ammonia are preferred.

Herein, the pH adjusting agents may be used alone, or in combination of two or more.

A content of the pH adjusting agent is not particularly limited, preferably being an amount allowing a pH value to be controlled in the preferred range which will be described later.

### [Other Component(s)]

The polishing composition according to the present invention may further contain a known component such as an abrasive grain(s) other than the abrasive grains described above, a chelating agent, a thickener, an oxidizing agent, a dispersing agent, a surface protecting agent, a wetting agent, a surfactant, an anticorrosive (rust inhibitor), an antiseptic agent, and an antifungal agent, and a dispersion stabilizer which will be described later. A content of the other component(s) may be appropriately set depending on the purpose of addition. Here, the dispersion stabilizer may include at least one phosphorus-containing acid selected from the group consisting of phosphoric acid and a condensate thereof, an organic phosphoric acid, phosphonic acid and an organic phosphonic acid. In the present specification, “organic phosphoric acid” refers to an organic compound having at least one phosphoric acid group (—OP(═O)(OH)₂), and “organic phosphonic acid” refers to an organic compound having at least one phosphonic acid group (—P(═O)(OH)₂). Further, in the present specification, “phosphoric acid and a condensate thereof, and organic phosphoric acid” are also simply referred to as “phosphoric acid-based acids”, and “phosphonic acid and organic phosphonic acid” are also simply referred to as “phosphonic acid-based acids”. These phosphorus-containing acids serve to change a zeta potential of alumina particles into minus (−) (negative conversion). The alumina particles with zeta potential converted into minus (−) cause electrostatic repulsion to each other to suppress aggregation, so that re-dispersibility of a condensed liquid can be improved.

Specific examples of the phosphorus-containing acid may include phosphoric acid (ortho-phosphoric acid), pyrophosphoric acid, tripolyphosphoric acid, tetrapolyphosphoric acid, hexametaphosphoric acid, methyl acid phosphate, ethyl acid phosphate, ethyl glycol acid phosphate, isopropyl acid phosphate, phytic acid (myo-inositol-1,2,3,4,5,6-hexaphosphate), 1-hydroxyethylidene-1,1-diphophonic acid (HEDP), nitrilotris(methylene phosphonic acid) (NTMP), ethylenediamine tetra(methylene phosphonic acid) (EDTMP), diethylenetriamine penta(methylene phosphonic acid), ethane-1,1-diphosphonic acid, ethane-1,1,2-triphosphonic acid, ethane-1-hydroxy-1,1-diphosphonic acid, ethanehydroxy-1,1,2-triphosphonic acid, ethane-1,2-dicarboxy-1,2-diphosphonic acid, and methane hydroxy phosphonic acid. Among these, from the viewpoint of improving balance among re-dispersibility, polishing rate and etching speed, phosphonic acid-based acids are preferred, organic phosphonic acids are more preferred, and 1-hydroxyethylidene-1,1-diphophonic acid (HEDP), nitrilotris(methylene phosphonic acid) (NTMP), and ethylenediamine tetra(methylene phosphonic acid) (EDTMP) are still more preferred. Herein, the phosphorus-containing acids may be used alone, or in combination of two or more.

[pH]

pH of the polishing composition according to the present invention is preferably 1 or more and 6 or less, or 8 or more and 12 or less, more preferably more than 1 and less than 5 or more than 8 and 11 or less, and particularly preferably 1.5 or more and less than 4. Within the above ranges, better balance between improved polishing rate and reduced surface roughness can be achieved. In particular, with an acidic polishing composition, a polishing rate can be more improved. The pH of the polishing composition is determined by the measurement method described in the following Examples.

### [Production Method of Polishing Composition]

A production method (preparation method) of the polishing composition is not particularly limited, and for example, a production method including stirring and mixing alumina particles, colloidal silica particles, a dispersing medium (preferably water), and, optionally other component(s) may be appropriately employed. The alumina particles, colloidal silica particles, dispersing medium and other component(s) are the same as those described in the item <Polishing composition>, and so the description is omitted here.

A temperature at which each of the components is mixed is not particularly limited, but ranges preferably from 10 to 40° C., and heating may be performed to increase a dissolution rate. A mixing time is also not particularly limited.

### [Object to be Polished]

The object to be polished with the polishing composition according to the present invention contains a resin and a filler.

The resin is not particularly limited, and examples thereof may include acrylic resins such as polymethyl(meth)acrylates, methylmethacrylate-methylacrylate copolymers, and urethane(meth)acrylate resins; epoxy resins; olefin resins such as ultra-high molecular weight polyethylene (UHPE); phenol resins; polyamide resins (PA); polyimide resins (PI); polyester resins such as polyethylene terephthalate (PET), polybutylene terephthalate (PBT), and unsaturated polyester resins; polycarbonate resins (PC); polyphenylene sulfide resins; polystyrene resins such as syndiotactic polystyrene (SPS); polynorbornene resins; polybenzoxazole (PBO); polyacetal (POM); modified polyphenylene ether (m-PPE); amorphous polyacrylate (PAR); polysulfone (PSF); polyether sulfone (PES); polyphenylene sulfide (PPS); polyether ether ketone (PEEK); polyether imide (PEI); fluorine resins; and liquid crystal polymer (LCP). In the present specification, “(meth)acrylic acid” refers to acrylic acid or methacrylic acid, and both acrylic acid and methacrylic acid. In the same manner, in the present specification, “(meth)acrylate” refers to acylate or methacrylate, or also both of acrylate and methacrylate. Among these, from the viewpoint of processability, a resin having a cyclic molecular structure is preferred. In other words, in a preferred embodiment of the present invention, the resin has a cyclic molecular structure. As the resin having such a cyclic molecular structure, an epoxy resin, a polycarbonate resin, or a polyphenylene sulfide resin is preferably used. The resins may be used alone, or in combination of two or more. Alternatively, the resin may be cured by a curing agent.

A material to constitute the filler is not particularly limited, and examples thereof include may glass, carbon, calcium carbonate, magnesium carbonate, barium sulfate, magnesium sulfate, aluminum silicate, titanium oxide, alumina, zinc oxide, silica (silicon dioxide), kaolin, talc, glass beads, sericite active white clay, bentonite, aluminum nitride, polyester, polyurethane and rubber. Among these, from the viewpoint of processability, glass and silica are preferred, and silica is particularly preferred.

Examples of a shape of filler may include a powder form, a spherical form, a fiber form and a needle form. Among these, from the viewpoint of processability, a spherical form and a fiber form are preferred, and a spherical form is more preferred. A size of the filler is not particularly limited. For example, in the case of filler in a spherical form, an average particle size is, for example, 0.01 to 50 μm, and preferably 1.0 to 6.5 μm. Also, in the case of filler in a fiber form, a major diameter is, for example, 100 to 300 μm, and preferably 150 to 250 μm, and a minor diameter is, for example, 1 to 30 μm, and preferably 10 to 20 μm.

The fillers may be used alone, or in combination of two or more.

Further, the object to be polished may contain a material different from the resin and filler in a surface to be polished in addition to them. Examples of the material may include copper (Cu), aluminum (Al), tantalum (Ta), tantalum nitride (TaN), titanium (Ti), titanium nitride (TiN), nickel (Ni), ruthenium (Ru), cobalt (Co), tungsten (W) and tungsten nitride (WN).

The object to be polished may be prepared from a resin and a filler, or may be prepared from a commercial product. Examples of the commercial product may include interlayer insulation materials “Ajinomoto Build-up Film” (ABF) GX13, GX92, GX-T31 and GZ41 (all manufactured by Ajinomoto Fine-Techno Co., Inc.); polycarbonate (PC) resin “Panlite (registered trademark)”, glass fiber reinforced grade (manufactured by Teijin Limited); and GF reinforced Durafide (registered trademark) PPS, and GFinorganic filler reinforced Durafide (registered trademark) PPS (both manufactured by Polyplastics Co., Ltd.).

### <Polishing Method>

Another embodiment of the present invention relates to a polishing method including a step of polishing an object to be polished with the polishing composition. Preferred examples of the object to be polished according to the present embodiment are the same described in [Object to be polished]. For example, it is preferable to polish an object to be polished containing a resin and a filler in a surface to be polished. In other words, the preferred embodiment of the polishing method according to the present invention includes a step of polishing an object to be polished containing a resin and a filler with the polishing composition.

Polishing an object to be polished with the polishing composition may be performed using an apparatus and conditions for use in usual polishing. Examples of the typical polishing apparatus may include a single side polishing machine and a double side polishing machine. In a single side polishing machine, an object to be polished is typically held with a retainer referred to as carrier, and a table platen with a polishing pad attached is pressed against one side of the object to be polished and rotated, while the polishing composition is supplied from above, so that the one side of the object to be polished is polished. In a double side polishing machine, an object to be polished is typically held with a retainer referred to as carrier, and table platens with a polishing pad attached are pressed against opposing surfaces of the object to be polished and rotated in the opposing directions, while the polishing composition is supplied from above, so that both sides of the object to be polished are polished. On this occasion, polishing is performed through a physical action caused by the friction between the polishing pad together with the polishing composition and the object to be polished, and through a chemical action on the object to be polished caused by the polishing composition. As the polishing pad, a porous material of nonwoven fabric, polyurethane, suede or the like may be used without particular limitation. It is preferable that the polishing pad be processed such that a polishing liquid is accumulated.

Examples of the polishing conditions include polishing load, rotation speed of table platen, rotation speed of carrier, flow rate of polishing composition, and polishing time. Although these polishing conditions are not particularly limited, for example, the polishing load (polishing pressure) per unit area of the object to be polished is preferably 0.1 psi (0.69 kPa) or more and 10 psi (69 kPa) or less, more preferably 0.5 psi (3.5 kPa) or more and 8.0 psi (55 kPa) or less, and still more preferably 1.0 psi (6.9 kPa) or more and 6.0 psi (41 kPa) or less. In general, the more the load is, the more the friction force of abrasive grains is, so that mechanical processing force is improved, and thus a polishing rate increases. Within the ranges, a sufficient polishing rate can be achieved, while damage to an object to be polished and occurrence of defects such as surface scratches caused by the load can be suppressed. It is preferable that the rotation speed of table platen and the rotation speed of carrier be 10 rpm (0.17 s⁻¹) to 500 rpm (8.3 s⁻¹). The supply rate of polishing composition may be a supply rate (flow rate) at which the polishing composition covers the whole of an object to be polished, and may be adjusted depending on the conditions such as a size of the object to be polished. Also, a method for supplying the polishing composition to a polishing pad is not particularly limited, and, for example, a continuous supply method with a pump or the like may be employed. Also, although the processing time is not particularly limited as long as desired processing results are obtained, a less time resulting from a high polishing rate is preferred.

Further, another embodiment of the present invention relates to a method of producing a polished object, including a step of polishing an object to be polished by the polishing method described above. Preferred examples of the object to be polished according to the embodiment is the same described in [Object to be polished]. As a preferred example, there may be a method for producing an electronic circuit board including polishing an object to be polished including a resin and a metal by the polishing method described above.

### EXAMPLES

The present invention will be described in more detail with the following Examples and Comparative Examples. However, the technical scope of the present invention is not limited only to the following Examples. Herein, “%” and “part” mean “mass %” and “part by mass”, respectively.

### <Measurement Method of Physical Property>

### [Average Particle Size of Alumina Particles]

Alumina particles (first abrasive grains) were subjected to measurement using a particle size distribution measuring apparatus (Microtrac particle size distribution measuring apparatus MT3300EX II, manufactured by MicrotracBEL Corp.) to determine a volume-based particle size distribution. In the resulting particle size distribution, a particle size indicating a 50% cumulative frequency from the small-particle-size end was defined as the average particle size of alumina particles (D₅₀).

### [Average Particle Size of Colloidal Silica Particles]

Colloidal silica particles (second abrasive grains) were subjected to measurement using a particle size distribution measuring apparatus (nano particle size measuring apparatus NANOTRAC WAVE II UPA-UT151, manufactured by MicrotracBEL Corp.) to determine a volume-based particle size distribution. In the resulting particle size distribution, a particle size indicating a 50% cumulative frequency from the small-particle-size end was defined as the average particle size of colloidal silica particles (D₅₀).

### [Average Major Diameter, Average Minor Diameter, and Aspect Ratio of Colloidal Silica Particles]

From an image of colloidal silica particles (second abrasive grains) measured by a scanning electron microscope (SEM) (product name: SU8000, manufactured by Hitachi High-Tech Corporation), 100 samples were selected at random to measure each of a major diameter and a minor diameter. From the measurement results, an average major diameter (μm) and an average minor diameter (μm) were calculated. Subsequently, using the resulting average major diameter (μm) and the average minor diameter (μm), the average major diameter was divided by the average minor diameter to calculate an aspect ratio (average major diameter/average minor diameter) of the colloidal silica particles.

[pH]

pH value of the polishing composition was checked by a pH meter (model number: LAQUA (registered trademark), manufactured by Horiba, Ltd.).

### Examples 1 to 14 and Comparative Examples 1 to 14

The first abrasive grains and the second abrasive grains or the first abrasive grains described in Table 1 and water in amounts described in Table 1 were stirred and mixed, to prepare each of polishing compositions (mixing temperature: about 25° C., mixing time: about 30 minutes). In Examples 1 to 8 and 10 to 14 and in Comparative Examples 1 to 14, an aqueous solution of 30 mass % malic acid was used to adjust the pH to the value described in Table 1. In Example 9, an aqueous solution of 48 mass % potassium hydroxide was used to adjust the pH to the value described in Table 1. In the following Table 1, “alumina” means α-alumina particles.

In the following Table 1, the colloidal silica particles having an average particle size of 0.08 μm were made by sodium silicate method and had an average particle size (D₅₀) of 0.08 μm and a span value [(D₉₀−D₁₀)/D₅₀] of 0.89. The colloidal silica particles having an average particle size of 0.02 μm were made by sodium silicate method and had an average particle size (D₅₀) of 0.02 μm and a span value [(D₉₀−D₁₀)/D₅₀] of 0.55. The colloidal silica particles having an average particle size of 0.05 μm were made by sodium silicate method and had an average particle size (D₅₀) of 0.05 μm and a span value [(D₉₀−D₁₀)/D₅₀] of 0.64. The colloidal silica particles having an average particle size of 0.2 μm were made by alkoxide method and had an average particle size (D₅₀) of 0.2 μm and a span value [(D₉₀−D₁₀)/D₅₀] of 0.98.

A polishing rate and surface roughness (Ra) of each the resulting polishing compositions were evaluated according to the methods described in [Polishing rate (polishing speed) 1] and [Surface roughness (Ra)], respectively. The results are shown in the following Table 1. In the following Table 1, “Mixing ratio” represents a mixing mass ratio of the first abrasive grains to the second abrasive grains (amount of first abrasive grains added (mass %)/amount of second abrasive grains added (mass %)). Also, “Particle size ratio” represents an average particle size ratio of the first abrasive grains to the second abrasive grains (average particle size of first abrasive grains (μm)/average particle size of second abrasive grains (μm)). “Increased proportion” is a value calculated based on the following formula and represents an increased proportion (%) of the polishing rate relative to the polishing rate of alumina only in an equal amount. For example, a polishing rate of the polishing composition of Example 1 was 0.49, while a polishing rate of the polishing composition of Comparative Example 1 containing alumina only in an equal amount was 0.14, so that the increased proportion in Example 1 is calculated to be 250(%) (=[(0.49−0.14)×100]/0.14).

$$Increased proportion = \qquad [ Formula 1 ]$$

$$\frac{\begin{matrix}( Polishing rate of polishing composition ) - \\ ( Polishing rate of alumina particle only in \\ equal amount in Comparative Example )\end{matrix}}{\begin{matrix}( Polishing rate of alumina particle only \\ in equal amount in Comparative Example )\end{matrix}} \times 100$$

### <Evaluation>

### [Polishing Rate (Polishing Speed) 1]

As an object to be polished, a mixture of an epoxy resin and a filler (spherical silica, average particle size=1.0 μm) with a filler content of 70 mass % was prepared (object to be polished 1; specific gravity: 1.9 g/cm³). Subsequently, the object to be polished (substrate) was polished with each of the polishing compositions using the following polishing apparatus and polishing conditions so as to evaluate a polishing rate (polishing speed) of the object to be polished 1 according to the following polishing rate evaluation method.

(Polishing apparatus and polishing conditions)
Polishing apparatus: small-sized table-top polishing machine (EJ380IN, manufactured by Engis Japan Corporation)
Diameter of table platen: 380 mm
Polishing pad: pad made of rigid polyurethane (IC1010, manufactured by NITTA DuPont Incorporated)
Rotation speed of platen (table platen): 90 rpm
Rotation speed of head (carrier): 90 rpm
Polishing pressure: 3.0 psi (210 g/cm³)
Flow rate of polishing composition: 20 ml/min
Polishing time: 5 min

(Evaluation Method of Polishing Rate)

1. Masses of an object to be polished before and after polishing were measured with an analytical balance XS205 (manufactured by Mettler-Toledo International Inc.). From a difference between the masses, the mass change ΔM (kg) of the object to be polished before and after polishing was calculated.

2. The mass change ΔM (kg) of the object to be polished before and after polishing was divided by the specific gravity of the object to be polished (specific gravity of material to be polished) to calculate a volume change ΔV (m³) of the object to be polished before and after polishing.

3. The volume change ΔV (m³) of the object to be polished before and after polishing was divided by an area S (m²) of a surface to be polished of the object to be polished to calculate a thickness change Δd (m) of the object to be polished before and after polishing.

4. The thickness change Δd (m) of the object to be polished before and after polishing was divided by a polishing time t (min), and a unit thereof was converted to (μm/min). The value was defined as polishing rate v (μm/min). Although a higher polishing rate is preferred, a polishing rate of 0.3 μm/min or more is acceptable, and a polishing rate of more than 0.45 μm/min is desirable.

### [Surface Roughness (Ra)]

Surface roughness Ra of an object to be polished (epoxy resin) after polishing which had been used for the evaluation of the polishing rate was measured with a noncontact-type surface profile measuring apparatus (laser microscope, VK-X200 manufactured by Keyence Corporation). The surface roughness Ra is a parameter representing an average of amplitude in the height direction of a roughness curve, i.e. an arithmetic average of a surface height of the object to be polished in a fixed field of view. The measurement range (viewing angle) of the noncontact-type surface profile measuring apparatus was set to be 95 μm×72 μm. Although a less surface roughness (Ra) is preferred, a surface roughness of less than 100 nm is acceptable, and a surface roughness of less than 50 nm is desirable.

TABLE 1

| | First abrasive grain | | | Second abrasive grain | | | | | | | | |
|---|---|---|---|---|---|---|---|---|---|---|---|---|
| | | Average | Amount | | Average | Amount | | Mixing | | | | |
| | | particle | added | | particle | added | | radio | Particle | Polishing | Increased | |
| | | size | [mass | | size | [mass | | (mass | size | rate | proportion | Ra |
| | Material | [μm] | %] | Material | [μm] | %] | pH | ratio) | ratio | [μm/min] | [%] | [nm] |
| Comparative Example 1 | Alumina | 0.3 | 5 | — | — | — | 2 | | | 0.14 | | 76 |
| Comparative Example 2 | Alumina | 0.3 | 6 | — | — | — | 2 | | | 0.15 | | 80 |
| Comparative Example 3 | Alumina | 0.3 | 5 | Colloidal | 0.02 | 1 | 2 | 5.0 | 15.0 | 0.21 | | 63 |
| | | | | alumina | | | | | | | | |
| Comparative Example 4 | Alumina | 0.3 | 5 | Fumed alumina | 0.69 | 1 | 2 | 6.0 | 0.4 | 0.29 | | 57 |
| Comparative Example 5 | Alumina | 0.3 | 5 | Layered silicate | 0.03 | 1 | 2 | 6.0 | 10.0 | 0.16 | | 49 |
| Comparative Example 6 | Alumina | 0.3 | 5 | Cellulose | 0.17 | 1 | 2 | 6.0 | 4.3 | 0.09 | | 77 |
| | | | | nanofiber | | | | | | | | |
| Example 1 | Alumina | 0.3 | 5 | Colloidal silica | 0.08 | 1 | 2 | 5.0 | 3.8 | 0.49 | 250 | 33 |
| Example 2 | Alumina | 0.3 | 5 | Colloidal silica | 0.02 | 1 | 2 | 6.0 | 15.0 | 0.33 | 136 | 29 |
| Example 3 | Alumina | 0.3 | 5 | Colloidal silica | 0.05 | 1 | 2 | 6.0 | 6.0 | 0.37 | 164 | 29 |
| Example 4 | Alumina | 0.3 | 5 | Colloidal silica | 0.20 | 1 | 2 | 6.0 | 1.5 | 0.30 | 114 | 46 |
| Example 5 | Alumina | 0.3 | 7.5 | Colloidal silica | 0.08 | 2.5 | 2 | 3.0 | 3.8 | 0.61 | | 28 |
| Example 6 | Alumina | 0.3 | 5 | Colloidal silica | 0.08 | 6 | 2 | 1.0 | 3.8 | 0.56 | 300 | 27 |
| Example 7 | Alumina | 0.3 | 2.5 | Colloidal silica | 0.08 | 7.5 | 2 | 0.3 | 3.8 | 0.59 | | 23 |
| Example 8 | Alumina | 0.3 | 2.5 | Colloidal silica | 0.08 | 7.5 | 6 | 0.3 | 3.8 | 0.35 | | 23 |
| Example 9 | Alumina | 0.3 | 2.5 | Colloidal silica | 0.08 | 7.5 | 10 | 0.3 | 3.8 | 0.48 | | 24 |
| Example 10 | Alumina | 0.4 | 5 | Colloidal silica | 0.08 | 1 | 2 | 5.0 | 5.0 | 0.41 | 28 | 50 |
| Example 11 | Alumina | 0.4 | 5 | Colloidal silica | 0.08 | 5 | 2 | 1.0 | 5.0 | 0.70 | 119 | 35 |
| Example 12 | Alumina | 0.4 | 5 | Colloidal silica | 0.08 | 7.5 | 2 | 0.7 | 5.0 | 0.91 | 184 | 38 |
| Comparative Example 7 | Alumina | 0.8 | 5 | — | — | — | 2 | | | 0.82 | | 104 |
| Example 13 | Alumina | 0.8 | 5 | Colloidal silica | 0.08 | 1 | 2 | 5.0 | 10.0 | 1.29 | 57 | 82 |
| Comparative Example 8 | Alumina | 1.2 | 5 | — | — | — | 2 | | | 0.66 | | 132 |
| Example 14 | Alumina | 1.2 | 5 | Colloidal silica | 0.08 | 1 | 2 | 5.0 | 15.0 | 1.29 | 95 | 89 |
| Comparative Example 9 | Alumina | 2.8 | 5 | — | — | — | 2 | | | 4.89 | | 135 |
| Comparative Example 10 | Alumina | 2.8 | 5 | Colloidal silica | 0.08 | | 2 | 5.0 | 35.0 | 4.75 | −3 | 110 |
| Comparative Example 11 | Colloidal | 0.08 | 1 | — | — | — | 2 | | | 0.10 | | 15 |
| | silica | | | | | | | | | | | |
| Comparative Example 12 | Colloidal | 0.2 | 5 | — | — | — | 2 | | | 0.13 | | 30 |
| | Silica | | | | | | | | | | | |
| Comparative Example 13 | Colloidal | 0.2 | 6 | — | — | — | 2 | | | 0.15 | | 28 |
| Comparative Example 14 | Colloidal | 0.2 | 5 | Colloidal silica | 0.08 | 1 | 2 | 5.0 | 2.5 | 0.13 | | 18 |

As shown in Table 1, use of the polishing composition according to the present invention allows the surface roughness to be reduced with a high polishing rate (polishing speed) being maintained. On the other hand, in the case of using polishing compositions containing alumina particles only in Comparative Examples 1 to 2 and 7 to 9 or using polishing compositions containing colloidal silica particles only in Comparative Examples 11 to 14, at least one of the polishing rate (polishing speed) and the surface roughness was poor. Further, in the case of using polishing compositions in Comparative Examples 3 to 6 and 14, with the size of abrasive grains (average particle size) in the scope of the present invention and with the combination of the abrasive grains out of the scope of the present invention, at least one of the polishing rate (polishing speed) and the surface roughness was poor.

### Examples 15 to 16, and Comparative Examples 15 to 16

A polishing composition was prepared in the same manner as in Example 1. Separately, a polishing composition was prepared in the same manner as in Comparative Example 1 described above.

Regarding each of the resulting polishing compositions, a polishing rate was evaluated for different objects to be polished according to the following method. Also, regarding the resulting polishing compositions, surface roughness (Ra) was evaluated in the same manner as in the method described in [Surface roughness (Ra)]. The results are shown in the following Table 2. In the following Table 2, the results of Example 1 and Comparative Example 1 are described together.

### <Evaluation>

### [Polishing Rate (Polishing Speed) 2]

As an object to be polished, a mixture of a polycarbonate resin and a filler (glass fiber, major diameter=218 μm, minor diameter=13 μm) with a filler content of 30 mass % was prepared (an object to be polished 2; specific gravity: 1.54 g/cm³). Subsequently, a polishing rate (polishing speed) of the object to be polished 2 was evaluated using the polishing composition in the same manner as in the method described in [Polishing rate (polishing speed) 1], except that the object to be polished 2 prepared as described above was used instead of the object to be polished 1 (Example 15 and Comparative Example 15). Although a higher polishing rate is preferred in the present evaluation, a polishing rate of more than 0.50 μm/min is acceptable, and a polishing rate of 0.65 μm/min or more is desirable. Also, although a less surface roughness (Ra) is preferred, a surface roughness of less than 500 nm is acceptable, and a surface roughness of less than 200 nm is desirable.

### [Polishing Rate (Polishing Speed) 3]

As an object to be polished, a mixture of a polyphenylene sulfide resin and a filler (spherical silica, average particle size=6.5 μm) with a filler content of 50 mass % was prepared (an object to be polished 3; specific gravity: 1.78 g/cm³). Subsequently, a polishing rate (polishing speed) of the object to be polished 3 was evaluated using the polishing composition in the same manner as in the method described in [Polishing rate (polishing speed) 1], except that the object to be polished 3 prepared as described above was used instead of the object to be polished 1 (Example 16 and Comparative Example 16). Although a higher polishing rate is preferred in the present evaluation, a polishing rate of more than 0.10 μm/min is acceptable, and a polishing rate of 0.11 μm/min or more is desirable. Also, although a less surface roughness (Ra) is preferred, a surface roughness of less than 250 nm is acceptable, and a surface roughness of less than 200 nm is desirable.

TABLE 2

| | Polishing rate | Increased | Ra |
|---|---|---|---|
| | [μm/min] | proportion [%] | [nm] |
| | Object to be polished 1 | | |
| Example 1 | 0.49 | 250 | 33 |
| Comparative | 0.14 | | 76 |
| Example 1 | | | |
| | Object to be polished 2 | | |
| Example 15 | 0.68 | 42 | 180 |
| Comparative | 0.48 | | 1500 |
| Example 15 | | | |
| | Object to be polished 3 | | |
| Example 16 | 0.13 | 44 | 180 |
| Comparative | 0.09 | | 260 |
| Example 16 | | | |

As shown in Table 2, use of the polishing compositions according to the present invention allows surface roughness of the objects to be polished containing various resins and fillers to be reduced, while maintaining a high polishing rate.

The present application is based on Japanese patent application No. 2020-209498 filed on Dec. 17, 2020, and a disclosed content thereof is incorporated herein as a whole by reference.

1. A polishing composition comprising alumina particles, colloidal silica particles, and a dispersing medium for use in polishing an object to be polished containing a resin and a filler, wherein
the alumina particles have an average particle size of less than 2.8 μm, and
the colloidal silica particles have an average particle size less than the average particle size of the alumina particles.

2. The polishing composition according to claim 1, wherein the colloidal silica particles have an average particle size of 0.02 μm or more and less than 0.20 μm.

3. The polishing composition according to claim 1, wherein the alumina particles have an average particle size of more than 0.2 μm and less than 1.2 μm.

4. The polishing composition according to claim 1, wherein a ratio of the average particle size of alumina particles to the average particle size of colloidal silica particles is more than 1.5 and less than 20.0.

5. The polishing composition according to claim 1, wherein a mixing mass ratio of the alumina particles to the colloidal silica particles is 0.3 or more and less than 5.0.

6. A polishing method comprising polishing an object to be polished containing a resin and a filler by using the polishing composition according to claim 1.

7. The method according to claim 6, wherein the resin has a cyclic molecular structure.

8. The method according to claim 6, wherein the filler is in a spherical form.
